(19) United States
(12) Patent Application Publication
(10) Pub. No.: US 2026/0260925 A1
(43) Pub. Date: Sep. 3, 2026

(54) MODULE-AS-TOOLING FOR MANUFACTURING BATTERIES

(71) Applicant: GM Global Technology Operations LLC, Detroit, MI (US)

(72) Inventor: Chariton Klavin, Davisburg, MI (US)

(73) Assignee: GM Global Technology Operations LLC, Detroit, MI (US)

(21) Appl. No.: 19/067,000

(22) Filed: Feb. 28, 2025

(51) Int. Cl. H01M 10/04; G01R 31/3842; G01R 31/389; H01M 10/44; H01M 50/209; H01M 50/211; H01M 50/249; H01M 50/258

(52) U.S. Cl. CPC H01M 10/0481; G01R 31/3842; G01R 31/389; H01M 10/446; H01M 50/209; H01M 50/211; H01M 50/249; H01M 50/258

(57) ABSTRACT

A method of manufacturing a battery module is provided and includes providing one or more battery cells, providing a modular base plate configured to receive the one or more battery cells, coupling the one or more battery cells to the modular base plate, compressing the one or more battery cells with the modular base plate one or more times, aging the one or more or more battery cells without removing the one or more battery cells from the modular base plate, and testing the one or more battery cells without removing the one or more battery cells from the modular base plate.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates generally to batteries and, more particularly, to manufacturing batteries.

In recent years, advancements in battery technology have focused on enhancing energy density, reducing charging times, and extending the overall lifespan of battery packs. Various methods and materials have been explored to improve the performance and durability of these battery packs. For instance, innovations in lithium-ion battery technology have led to significant improvements in energy storage capabilities and thermal management. Additionally, the integration of advanced battery management systems (BMS) has been instrumental in monitoring and optimizing the performance of battery cells, ensuring balanced charging and discharging cycles.

Despite these advancements, the manufacturing process of battery packs remains a complex and intricate task. It can involve the precise assembly of numerous battery cells, the implementation of thermal management systems, and the integration of electronic controls. The ongoing challenge is to develop manufacturing techniques that can consistently produce high-quality battery packs while meeting the stringent performance and reliability standards required for automotive as well as other applications.

### SUMMARY

In one configuration, a method of manufacturing a power reservoir is provided and includes providing one or more battery cells, providing one or more modular base plates configured to receive the one or more battery cells, assembling one or more battery modules that each includes one of the modular base plates and at least one of the one or more battery cells, compressing the one or more battery cells with the one or more modular base plates one or more times, aging the one or more or more battery cells without removing the one or more battery cells from the one or more modular base plates, testing the one or more battery cells without removing the one or more battery cells from the one or more modular base plates, and arranging the one or more battery modules in a battery pack.

The method includes one or more of the following optional aspects or steps. For example, providing the one or more battery cells further includes providing one or more prismatic battery cells.

According to at least one aspect, providing the one or more battery cells further includes providing one or more pouch battery cells.

According to another aspect, the method further includes filling the one or more battery cells with an electrolyte solution. The method further includes sealing the one or more battery cells with a laser. Compressing the one or more battery cells with the one or more modular base plates further includes compressing the one or more battery cells during and after the one or more battery cells are filled with the electrolyte solution.

According to one example, compressing the one or more battery cells with the one or more modular base plates further includes applying pressure to the one or more battery cells to pack layers within the one or more battery cells and eliminate air gaps within the one or more battery cells.

According to another example, testing the one or more battery cells further includes charging and discharging the one or more battery cells. Testing the one or more battery cells further includes monitoring the one or more battery cells for changes in voltage, capacity, and internal resistance.

According to at least one aspect, aging the one or more battery cells further includes releasing built-up pressure from the one or more battery cells.

In another configuration, a method of manufacturing a battery module is provided and includes providing one or more battery cells, providing a modular base plate configured to receive the one or more battery cells, coupling the one or more battery cells to the modular base plate, compressing the one or more battery cells with the modular base plate one or more times, aging the one or more or more battery cells without removing the one or more battery cells from the modular base plate, and testing the one or more battery cells without removing the one or more battery cells from the modular base plate.

The method includes on or more of the following optional aspects or steps. For example, providing the one or more battery cells further includes providing one or more prismatic battery cells.

According to at least one aspect, providing the one or more battery cells further includes providing one or more pouch battery cells.

According to another aspect, the method further includes filling the one or more battery cells with an electrolyte solution. Compressing the one or more battery cells with the modular base plate further includes compressing the one or more battery cells during and after the one or more battery cells are filled with the electrolyte solution. The method further includes sealing the one or more battery cells with a laser.

According to at least one example, compressing the one or more battery cells with the modular base plate further includes applying pressure to the one or more battery cells to pack layers within the one or more battery cells and eliminate air gaps within the one or more battery cells.

According to another example, testing the one or more battery cells further includes charging and discharging the one or more battery cells. Testing the one or more battery cells further includes monitoring the one or more battery cells for changes in voltage, capacity, and internal resistance.

According to at least one aspect, aging the one or more battery cells further includes releasing built-up pressure from the one or more battery cells.

### BRIEF DESCRIPTION OF THE DRAWINGS

The drawings described herein are for illustrative purposes only of selected configurations and are not intended to limit the scope of the present disclosure.

FIG. 1 is a front perspective view of a vehicle according to principles of the present disclosure;

FIG. 2A is a perspective view of a battery cell according to the principles of the present disclosure;

FIG. 2B is a perspective view of a battery module including one or more of the battery cells of FIG. 2A arranged on a modular base plate according to the principles of the present disclosure;

FIG. 2C is a perspective view of a battery pack including one or more of the battery modules of FIG. 2B according to the principles of the present disclosure; and

FIG. 3 is a flow diagram providing a method of manufacturing a power reservoir in accordance with the principles of the present disclosure.

Corresponding reference numerals indicate corresponding parts throughout the drawings.

### DETAILED DESCRIPTION

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed.

When an element or layer is referred to as being “on,” “engaged to,” “connected to,” “attached to,” or “coupled to” another element or layer, it may be directly on, engaged, connected, attached, or coupled to the other element or layer, or intervening elements or layers may be present. In contrast, when an element is referred to as being “directly on,” “directly engaged to,” “directly connected to,” “directly attached to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The terms “first,” “second,” “third,” etc. may be used herein to describe various elements, components, regions, layers and/or sections. These elements, components, regions, layers and/or sections should not be limited by these terms. These terms may be only used to distinguish one element, component, region, layer or section from another region, layer or section. Terms such as “first,” “second,” and other numerical terms do not imply a sequence or order unless clearly indicated by the context. Thus, a first element, component, region, layer or section discussed below could be termed a second element, component, region, layer or section without departing from the teachings of the example configurations.

In this application, including the definitions below, the term “module” may be replaced with the term “circuit.” The term “module” may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term “code,” as used above, may include software, firmware, and/or microcode, and may refer to programs, routines, functions, classes, and/or objects. The term “shared processor” encompasses a single processor that executes some or all code from multiple modules. The term “group processor” encompasses a processor that, in combination with additional processors, executes some or all code from one or more modules. The term “shared memory” encompasses a single memory that stores some or all code from multiple modules. The term “group memory” encompasses a memory that, in combination with additional memories, stores some or all code from one or more modules. The term “memory” may be a subset of the term “computer-readable medium.” The term “computer-readable medium” does not encompass transitory electrical and electromagnetic signals propagating through a medium, and may therefore be considered tangible and non-transitory memory. Non-limiting examples of a non-transitory memory include a tangible computer readable medium including a nonvolatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

The non-transitory memory may be physical devices used to store programs (e.g., sequences of instructions) or data (e.g., program state information) on a temporary or permanent basis for use by a computing device. The non-transitory memory may be volatile and/or non-volatile addressable semiconductor memory. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described herein can be realized in digital electronic and/or optical circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

In general, manufacturing batteries can include electrode manufacturing, cell assembly, cell finishing (i.e., formation), and module and/or pack assembly.

Electrode manufacturing can include several steps to ensure high performance and longevity of the batteries. Initially, active materials such as lithium cobalt oxide for the cathode and graphite for the anode can be mixed with conductive additives and binders to form a slurry. The slurry can then be uniformly coated onto a current collector, typically aluminum for the cathode and copper for the anode, using techniques like doctor blade coating or slot-die coating. The coated electrodes can then be dried to remove solvents, calendared to achieve the desired thickness and density, and finally cut into precise shapes. Quality control measures, including thickness measurements and surface inspections, are essential throughout this process to ensure consistency and reliability in the final battery cells.

Cell assembly is a process that involves stacking or winding the prepared electrodes with a separator to form a cell. In a typical lithium-ion battery, the anode and cathode are alternately layered with a separator in between to prevent short circuits while allowing ionic conductivity. This assembly can be done in a flat, stacked configuration or a cylindrical, wound configuration, depending on the battery design. Once the electrode-separator assembly is complete, it is inserted into a casing, which can be a hard metal shell (e.g., cylindrical or prismatic can) or a flexible pouch, for example. The cell can then be filled with an electrolyte solution, which facilitates the movement of ions between the electrodes during charging and discharging. The casing is sealed to prevent leakage and contamination, ensuring the integrity of the cell.

Cell finishing (i.e., formation) is a step in battery manufacturing where the assembled cells undergo initial charging and discharging cycles. This process helps to form the solid electrolyte interphase (SEI) layer on the anode, which can be desirable for the cell's long-term stability and performance. During formation, cells are charged and discharged under controlled conditions to activate the electrochemical materials and ensure proper functioning. This step can also provide an opportunity to detect defects or inconsistencies in the cells, which can be addressed before the batteries are shipped (i.e., transported) outside of a manufacturing facility. The formation process can take several hours to days, depending on the specific battery chemistry and design, and is followed by aging, where the cells are stored for a period to stabilize their performance.

Once individual cells are finished, they are assembled into modules and packs to create a complete battery system. This involves communicatively coupling multiple cells to achieve a desired voltage and capacity. The cells are typically housed in a protective casing and connected using busbars or flexible connectors. Thermal management systems, such as cooling plates or heat sinks, are integrated to manage the heat generated during operation. Additionally, battery management systems (BMS) are installed to monitor and control the state of charge, temperature, and overall health of the battery pack. The assembled modules or packs undergo rigorous testing to ensure they meet safety, performance, and reliability standards before being integrated into their final applications, such as electric vehicles or energy storage systems.

Heretofore, the battery manufacturing process has relied on compression trays and aging trays. In general, compression trays have been used in the battery manufacturing process to apply uniform pressure to the battery cells during certain stages of production. One of the primary uses of compression trays is during the cell assembly process, particularly for pouch cells. After the electrodes and separators are stacked or wound and placed into the pouch, the pouch is sealed, and the cell is placed in a compression tray. The compression tray applies pressure to ensure that the layers within the cell are tightly packed and that there are no air gaps, which can affect the cell's performance and reliability. Compression can be desirable for improving the contact between the electrodes and the separator, enhancing the overall electrochemical performance of the cell. Additionally, compression trays can be used during the electrolyte filling process to ensure that the electrolyte is evenly distributed throughout the cell.

Aging trays can be used to hold and organize battery cells during the aging process, which follows the formation step in battery manufacturing. After the initial charging and discharging cycles, cells are placed in aging trays and stored for a specific period, which can range from several days to weeks. The purpose of aging is to allow the cells to stabilize and to ensure that any residual reactions within the cell materials are completed. During this time, the cells are monitored for changes in voltage, capacity, and internal resistance. Aging helps to identify any cells that may have defects or inconsistencies that were not detected during the formation process. By using aging trays, manufacturers can efficiently manage and track the aging process, ensuring that each cell meets any necessary standards (e.g., quality, performance, etc.) before being assembled into modules or packs.

Gigafactories (i.e., giga-scale plants), as well as other manufacturing environments, require a substantial number of both types (i.e., compression and aging) of trays and significant infrastructure (e.g., storage racks, cranes, etc.) to store and move the trays throughout the manufacturing process. Additionally, the battery cells must be moved back and forth between the aging trays and the compression trays during traditional manufacturing processes. In at least one instance, battery cells are initially arranged in an aging tray, moved to a compression tray, returned to the aging tray, moved back to the compression tray, and finally returned to the aging tray. With respect to at least some of the principles of the present disclosure, a battery and a method of manufacturing the same eliminates the temporary (i.e., momentary) use of compression trays and/or aging trays that are relied on during traditional battery manufacturing processes. As will be discussed in greater detail below, an illustrative example of a modular base plate is provided and is configured to operate as tooling during manufacturing and serve as a fixture (i.e., module) of a battery pack upon installation.

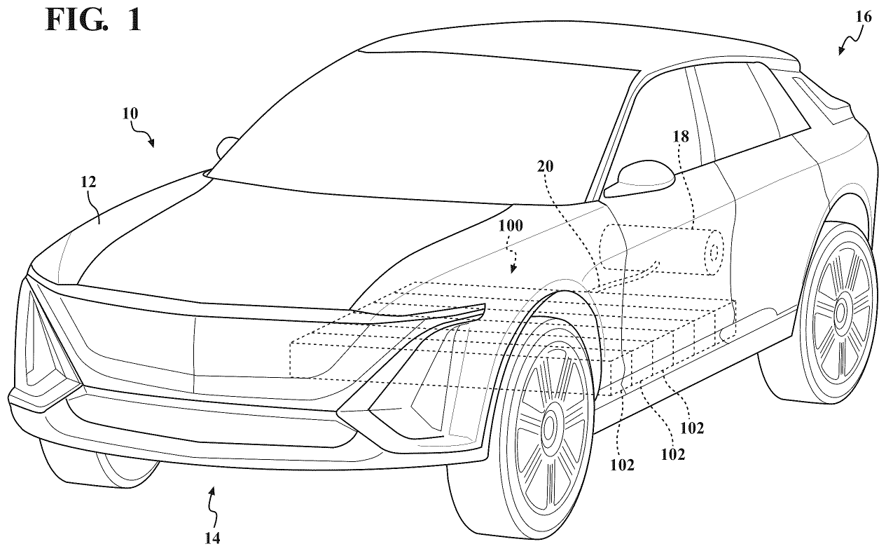

With reference to FIG. 1, an illustrative example of a vehicle 10 is provided. The vehicle 10 includes a body 12 that extends between a first end 14 and a second end 16. The vehicle 10 includes an electric motor 18 communicatively coupled to a power reservoir 100 via a cable 20. The power reservoir 100 can include one or more battery modules 102 coupled to the body 12 and arranged between the first end 14 and the second end 16.

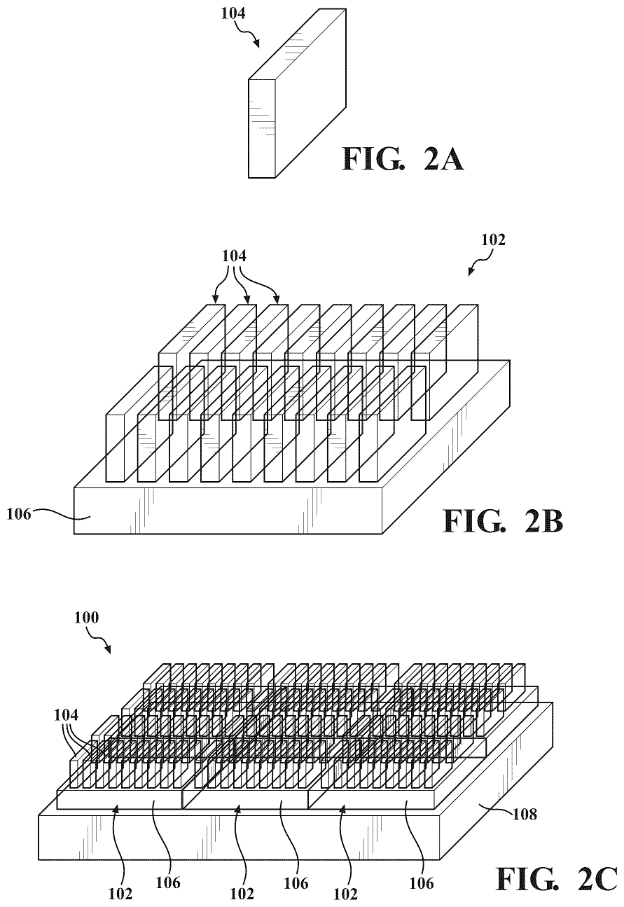

With reference to FIGS. 2A and 2B, each of the battery modules 102 can include one or more battery cells 104 (FIGS. 2A and 2B) that are arranged with respect to a modular base plate 106 (FIG. 2B). The one or more battery cells 104 can be pouch cells, prismatic cells, or another type of cell commonly used in the automotive industry. In at least one configuration, the one or more battery cells 104 can be battery cells that benefit from compression and/or aging during the manufacturing process.

The modular base plate 106 is configured to receive and retain one or more of the battery cells 104 during and after the manufacturing process is completed. According to at least one aspect, the one or more battery cells 104 can be assembled and coupled to or otherwise attached to the modular base plate 106 prior to the battery cells 104 undergoing any cell finishing or formation processes (e.g., compression and/or aging). The modular base plate 106 is configured so that the battery cells 104 are no longer moved (i.e., shuffled) between designated trays (e.g., a compression tray and an aging tray) at any stage of the manufacturing process. Instead, once the battery cells 104 are arranged on the modular base plate 106, any compression, aging, or other processes for treating (e.g., finishing) the one or more battery cells 104 is carried out by the modular base plate 106. In other words, the modular base plate 106 is configured with tooling that is desirable for further processing the one or more battery cells 104.

One or more of the battery modules 102 (i.e., the one or more battery cells 104 and the modular base plate 106) can be further arranged in a battery pack 108, as shown in FIG. 2C. Upon being arranged in the battery pack 108, the modular base plate 106 is configured to serve as a fixture that supports, retains, and/or removes heat from the one or more battery cells 104 during and after operation, for example. According to one aspect, the one or more battery modules 102 can be swapped out of the battery pack 108 with another battery module 102 with ease.

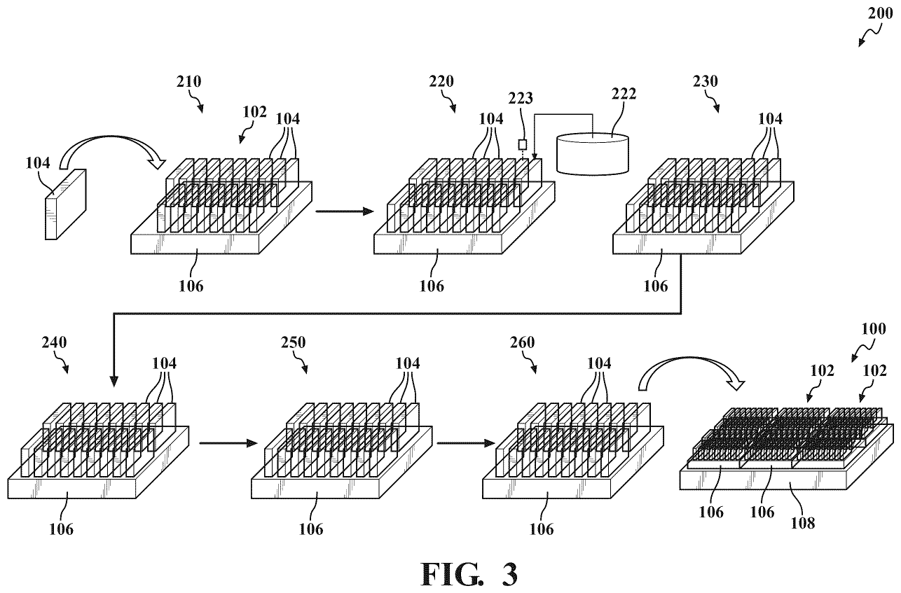

With reference to FIG. 3, an example configuration of a method 200 of manufacturing a power reservoir according to the principles of the present disclosure is provided. Note, FIG. 3 is simply one illustrative configuration, and other configurations are certainly possible based on the principles of the present disclosure.

At 210, the one or more battery modules 102 are assembled. In other words, the one or more battery cells 104 are arranged on and coupled to or otherwise attached to the modular base plate 106. While one or more of the battery cells 104 can be swapped out or replaced after being tested, a majority, if not all, the battery cells 104 will not be removed from the modular base plate 106 from this point forward during the manufacturing process.

At 220, the battery cells 104 are further assembled. For instance, while arranged on the modular base plate 106 the one or more battery cells 104 can be filled with an electrolyte solution 222, which facilitates the movement of ions between electrodes in the battery cells 104 during charging and discharging. The one or more battery cells 104 are then sealed using a laser 223 or another method found in the automotive industry to prevent leakage and contamination.

At 230, the battery cells 104 are aged for hours, days, weeks, or months, depending on the battery design, so that the electrolyte solution 222 can soak into the electrodes of the battery cells 104. This process is sometimes referred to as a wetting process. Gases are sometimes generated or trapped within the battery cells 104 during this process, thus, it can be desirable to release any pressure that builds up within the battery cells 104 during this stage in the manufacturing process.

At 240, the battery cells 104 undergo a sequence of processes that are sometimes referred to as cell finishing or formation. The battery cells 104 can undergo cycles of compression via the modular base plate 106. Compression can be desirable for forming a solid electrolyte interphase (SEI) layer on an anode (not shown), which can be desirable for long-term stability and performance of the battery cells 104. During formation, battery cells 104 are charged and discharged under controlled conditions to activate the electrochemical materials and ensure proper functioning. According to one aspect, compressing the more battery cells 104 includes applying uniform pressure to the one or more battery cells 104. The modular base plate 106 can be configured to apply a consistent amount of pressure and in a manner that helps pack layers (i.e., battery internals) within the one or more battery cells 104 and/or eliminate air gaps within the one or more battery cells 104. According to another aspect, the one or more battery cells 104 can be compressed with the modular base plate 106 before, during, and/or after the electrolyte solution 222 is added to the one or more battery cells 104.

At 250, the battery cells 104 can be aged again using the modular base plate 106. The duration of the aging process can be hours, days, weeks, or even months and can be selected depending on the design of the battery. The aging process can be desirable to allow the battery cells 104 to stabilize and to ensure that any residual reactions within the cell materials are completed. During this time, the battery cells 104 can be monitored for changes in voltage, capacity, and internal resistance. Aging helps to identify any of the battery cells 104 that may have defects or inconsistencies that were not detected during the formation process.

At 260, the one or more battery modules 102 can be arranged in the battery pack 108 for use in a vehicle, a medical device, and/or a residential or commercial energy storage system, for example. The modular base plate 106 is configured to become a fixture of the battery pack 108. Thus, the modular base plate 106 is configured for assembly and formation of the battery cells 104 as well as supporting and retaining the battery cells 104 with respect to the battery pack 108. Eliminating the need for separate compression and aging trays can be desirable for reduce costs and freeing up space within manufacturing environments.

A number of implementations have been described. Nevertheless, it will be understood that various modifications may be made without departing from the spirit and scope of the disclosure. Accordingly, other implementations are within the scope of the following claims.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

What is claimed is:

1. A method of manufacturing a power reservoir for a vehicle, comprising:
providing one or more battery cells;
providing one or more modular base plates configured to receive the one or more battery cells;
assembling one or more battery modules that each includes one of the modular base plates and at least one of the one or more battery cells;
compressing the one or more battery cells with the one or more modular base plates one or more times;
aging the one or more or more battery cells without removing the one or more battery cells from the one or more modular base plates;
testing the one or more battery cells without removing the one or more battery cells from the one or more modular base plates;
arranging the one or more battery modules in a battery pack; and
installing the battery pack in the vehicle.

2. The method of claim 1, wherein providing the one or more battery cells further comprises providing one or more prismatic battery cells.

3. The method of claim 1, wherein providing the one or more battery cells further comprises providing one or more pouch battery cells.

4. The method of claim 1, further comprising filling the one or more battery cells with an electrolyte solution.

5. The method of claim 4, further comprising sealing the one or more battery cells with a laser.

6. The method of claim 4, wherein compressing the one or more battery cells with the one or more modular base plates further includes compressing the one or more battery cells during and after the one or more battery cells are filled with the electrolyte solution.

7. The method of claim 1, wherein compressing the one or more battery cells with the one or more modular base plates further includes applying pressure to the one or more battery cells to pack layers within the one or more battery cells and eliminate air gaps within the one or more battery cells.

8. The method of claim 1, wherein testing the one or more battery cells further includes charging and discharging the one or more battery cells.

9. The method of claim 8, wherein testing the one or more battery cells further includes monitoring the one or more battery cells for changes in voltage, capacity, and internal resistance.

10. The method of claim 1, wherein aging the one or more battery cells further includes releasing built-up pressure from the one or more battery cells.

11. A method of manufacturing a battery module, comprising:
providing one or more battery cells;
providing a modular base plate configured to receive the one or more battery cells;
coupling the one or more battery cells to the modular base plate;
compressing the one or more battery cells with the modular base plate one or more times;
aging the one or more or more battery cells without removing the one or more battery cells from the modular base plate; and
testing the one or more battery cells without removing the one or more battery cells from the modular base plate.

12. The method of claim 11, wherein providing the one or more battery cells further comprises providing one or more prismatic battery cells.

13. The method of claim 11, wherein providing the one or more battery cells further comprises providing one or more pouch battery cells.

14. The method of claim 11, further comprising filling the one or more battery cells with an electrolyte solution.

15. The method of claim 14, wherein compressing the one or more battery cells with the modular base plate further includes compressing the one or more battery cells during and after the one or more battery cells are filled with the electrolyte solution.

16. The method of claim 15, further comprising sealing the one or more battery cells with a laser.

17. The method of claim 11, wherein compressing the one or more battery cells with the modular base plate further includes applying pressure to the one or more battery cells to pack layers within the one or more battery cells and eliminate air gaps within the one or more battery cells.

18. The method of claim 11, wherein testing the one or more battery cells further includes charging and discharging the one or more battery cells.

19. The method of claim 18, wherein testing the one or more battery cells further includes monitoring the one or more battery cells for changes in voltage, capacity, and internal resistance.

20. The method of claim 11, wherein aging the one or more battery cells further includes releasing built-up pressure from the one or more battery cells.
